(19) United States
(12) Patent Application Publication
(10) Pub. No.: US 2025/0316504 A1
(43) Pub. Date: Oct. 9, 2025

(54) CLEANING DEVICE FOR SEMICONDUCTOR AND FLAT PANEL DISPLAY PROCESSING TOOLS

(71) Applicant: Applied Materials, Inc., Santa Clara, CA (US)

(72) Inventors: Cheng-hang Hsu, New Taipei City (TW); Roman Mostovoy, San Francisco, CA (US); Arun Ramaswamy Srivatsa, San Jose, CA (US)

(21) Appl. No.: 18/630,450

(22) Filed: Apr. 9, 2024

(51) Int. Cl. H01L 21/67; B08B 5/04; B08B 7/00; B08B 7/04

(52) U.S. Cl. CPC H01L 21/67028; B08B 5/04; B08B 7/0057; B08B 7/04; H01L 21/67248; H01L 21/67253

(57) ABSTRACT

Technologies related to maintaining and cleaning semiconductor processing chamber components and tools are described. A cleaning device may have a first end forming a nozzle and a second end configured to coupled to a particle counter. A first section of the nozzle is attached to a vacuum. A second section of the nozzle is attached to a first contamination removal mechanism of a plurality of contamination removal mechanisms. A third section of the nozzle is attached to a second contamination removal mechanism of the plurality of contamination removal mechanisms. A selection mechanisms selectively enables one or more of the plurality of contamination removal mechanisms.

### BACKGROUND

In the semiconductor industry, devices are fabricated by a number of manufacturing processes producing structures of ever-decreasing size. As the critical dimensions for semiconductor devices continue to shrink, there is an unyielding pressure to improve the cleanliness of the processing environment within a semiconductor process chamber. Surfaces of chamber components can aggregate particle sources generated during substrate production. These particle sources can cause particle defects on substrates. While high quality materials are often used in chamber components to reduce particle defects, scheduled cleaning downtime is still sometimes implemented to decontaminate the chamber.

### BRIEF SUMMARY

Embodiments of the present disclosure relate to the cleaning of components within a semiconductor processing chamber. In one embodiment, a device has a first end forming a nozzle and a second end configured to couple to a metrology tool, such as particle density counter. The nozzle may be partitioned into a plurality of sections. A vacuum channel may extend through the body from the nozzle to the second end. A first section of the nozzle may be coupled to the vacuum channel. A second section of the nozzle may be coupled to a first contamination removal mechanism. A third section of the nozzle may be coupled to a second contamination removal mechanism. A selection mechanism may be configured to selectively enable at least one of the plurality of contamination removal mechanisms.

In another embodiment, a device has a first end forming multiple nozzles and a second end configured to couple to a particle density counter. A vacuum channel may extend through the body from the first end to the second end. The vacuum channel may be coupled to one or more of the nozzles. A first nozzle may be coupled to a first contamination removal mechanism. A second nozzle may be coupled to a second contamination removal mechanism. A selection mechanism may be configured to selectively enable at least one of the plurality of contamination removal mechanisms.

In another embodiment, a method includes selectively enabling a first contamination removal mechanism of multiple contamination removal mechanisms. The device may then remove particles from a cleaning surface using the first contamination removal mechanism. The device may then gather sensor information corresponding to an effectiveness of the first contamination removal mechanism. The first sensor information may include at least one of a particle density metric or a surface environment metric. The surface environment metric may be one of an electrostatic charge metric, a humidity metric, or a temperature metric. The method may further include selectively enabling, based on the first sensor information, a second contamination removal mechanism of the multiple contamination removal mechanisms. The device may then remove particles from the cleaning surface using the second contamination removal mechanisms.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a sectional view of a processing chamber according to an embodiment;

FIG. 2 illustrates a cleaning device, according to one embodiment.

FIGS. 3A-D illustrate exemplary nozzles of a cleaning device, according to one embodiment.

FIG. 4A-B illustrate a cleaning device with a particle counter, according to one embodiment.

FIG. 5A-B illustrate a cleaning device with an elongated body, according to one embodiment.

FIG. 6 illustrates a method of using a cleaning device, according to one embodiment.

### DETAILED DESCRIPTION

Technologies related to maintaining and cleaning semiconductor processing chamber components and tools are described. Performance and yield associated with these chambers (e.g., of substrates manufactured using these chambers) may be tracked for the chambers, especially as semiconductor and flat panel devices become smaller and more densely packed with increasingly complex integrated circuits (ICs). Both performance and yield of processed substrates are affected, among other things, by an overall cleanliness of the chamber. Additionally, performance of a chamber may be measured based at least in part on a ratio between uptime (i.e., time that the chamber is producing or processing substrates) and downtime (i.e., time that the chamber is not producing or processing substrates, such as when the chamber is being cleaned). Unfortunately, in each step of processing semiconductor/panel substrates (e.g., using processes that include exposure to incoming gases including chemical pre-cursors, forming films on substrates, performing metrology and/or inspection of substrates, etc.), process parameters gradually drift and chamber components are becoming dirtier (e.g., by attracting particles, by films forming on the chamber components, by wear on the chamber components, etc.). Drifting parameters and dirty chamber components may significantly reduce production yield associated with a process chamber, which may inherently affect the performance of the chamber.

To address this reduced production yield, chambers regularly undergo downtime for cleaning. In many cases, field engineer(s) use tools, such as a traditional compressed dry air (CDA) gun and cleanroom wipes, to clean a process chamber. However, this downtime can routinely last up to 100 hours or more, which significantly reduces uptime of the process chamber and increases cost of ownership. This phenomenon also applies to other manufacturing equipment, such as inspection tools, metrology tools, transfer tools, and so on. Conventional cleaning tools (e.g., CDA gun and cleanroom wipes) do not provide quantified sensor information to determine whether a surface has been adequately cleaned. Thus, a field engineer using these conventional cleaning tools is prone to either under-clean (e.g., inadequately clean so as to leave the surface dirty) or over-clean (e.g., actively clean a surface longer than it takes to fully clean) a surface. If the surface is under-cleaned, the process chamber (or other manufacturing equipment) may have lower or inadequate production yields, and the process chamber (or other manufacturing equipment) may undergo downtime for additional cleaning sooner than anticipated. If the surface is over-cleaned, the chamber may have had a longer downtime than called for, which inherently impacts the overall productivity of the chamber. Embodiments address these issues by providing a cleaning tool with a metrology tool, such as a particle density counter, that increases chamber uptime by reducing chamber downtime for cleaning.

A field engineer may use a traditional CDA gun and cleanroom wipes to clean parts of a process chamber and/or chamber surface (or other manufacturing equipment). The CDA gun can blow particles into the air, which may allow the particles to re-deposit back onto surface or be re-distributed in the air. Particles re-depositing onto the surface or re-distributing in the air compromises the cleanliness of the surface or chamber being cleaned. Additionally, the CDA gun and cleanroom wipes are not efficient when van der Waals or electrostatic forces significantly influence the particles (e.g., such as for smaller particles, up to and including sub-micron (<1 μm) particles). Moreover, for some process chambers (such as for manufacturing of semiconductors), solvents that dissolve organic contaminations are not allowed. Thus, there is currently no cleaning tool able to effectively remove all types of particles (organic or inorganic) within a process chamber. Embodiments address these issues by providing a cleaning tool that is able to effectively remove all types of particles within a chamber, no matter if the particle is organic, inorganic, or influenced by van der Waals or electrostatic forces.

Moreover, some chamber components may not currently be cleaned by a traditional CDA gun or cleanroom wipe due to the component's size or shape (e.g., a bellow, screw hole, sharp corner, deep hole, or the like). In contrast, a cleaning tool described in embodiments herein is able to effectively clean surfaces of components in a chamber that conventional tools cannot reach due to the component's size or shape.

Aspects and embodiments of the present disclosure provide a solution to the above-described deficiencies and others by providing devices and methods for maintaining, cleaning, and verifying cleanliness (with in-situ metrology) of a chamber and chamber components. A group of chamber components and/or manufacturing equipment that may be maintained and cleaned using devices and methods of the present disclosure includes, but is not limited to: physical vapor deposition (PVD) components/chambers, atomic later deposition (ALD) components/chambers, chemical vapor deposition (CVD) components/chambers, etching components/chambers, fluorinated ethylene propylene (FEP) components, electrochemical plating (ECP) components, ion implant components, substrate transport components, factory interfaces, load locks, transfer chambers, and metrology tools such as components used for surface inspection and defect analysis (e.g., Surfscan), scanning electron microscopes (SEMs), critical dimension SEMs (CD-SEMs), and bright and dark optical inspection tools. The present disclosure may also provide a solution for maintaining, cleaning, and verifying cleanliness of flat panel display (FPD) processing tools, such as tools used in the fabrication and assembly of flat panel displays such as liquid crystal displays (LCDs), organic light-emitting diodes (OLEDs), and others. FPD processing tools may include, but are not limited to, photolithography components, deposition components, etching components, metrology components, and assembly components.

Aspects and embodiments of the present disclosure provide a cleaning tool (also referred to as a cleaning device) having multiple contamination removal mechanisms. The cleaning tool may have a first end that forms a nozzle and a second end configured to attach to a particle density counter or other similar metrology tool. A vacuum channel may extend from the nozzle to the particle density counter. The nozzle may be partitioned into multiple sections. A first section of the nozzle may be coupled to the vacuum channel. A second section of the nozzle may be coupled to a first contamination removal mechanism. A third section of the nozzle may be coupled to a second contamination removal mechanism different from the first contamination removal mechanism. The cleaning tool may have a selection mechanism configured to selectively enable at least one of the plurality of contamination removal mechanisms. The plurality of contamination removal mechanisms may include at least two of a carbon dioxide (CO₂) snow dispenser, an ionizer, an ultrasonic gas dispenser, and a heated gas dispenser. Other contamination removal mechanisms may also be used. In embodiments, the cleaning device is a hand-held device, and may optionally have a gun shape.

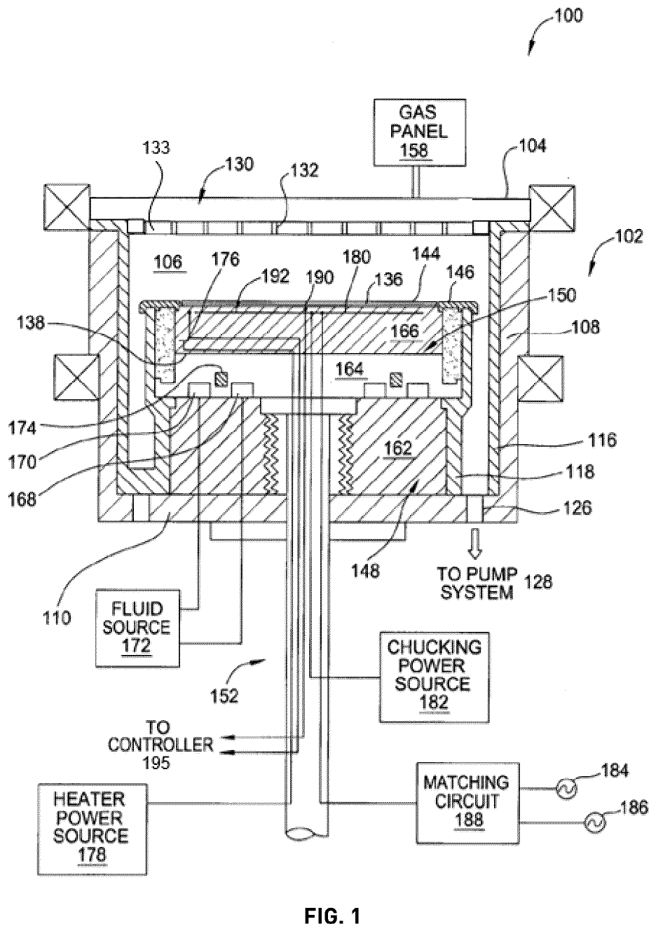

FIG. 1 is a sectional view of a semiconductor processing chamber 100, in accordance with one embodiment. The processing chamber 100 may be used for processes in which a corrosive plasma environment is provided. For example, the processing chamber 100 may be a chamber for a plasma etcher or plasma etch reactor, a plasma cleaner, and so forth. In alternative embodiments other processing chambers may be used, which may or may not be exposed to a corrosive plasma environment. Some examples of process chambers include a chemical vapor deposition (CVD) chamber, a physical vapor deposition (PVD) chamber, an ion assisted deposition (IAD) chamber, an atomic later deposition (ALD) chamber, an etch chamber, an oxidation chamber, an ion implanter, and other types of processing chambers. Any chamber components of the process chambers may be cleaned using a cleaning tool as described in embodiments herein. Other examples of manufacturing equipment that may be cleaned using the cleaning tool described in embodiments herein include factory interfaces, load locks, aligner stations, transfer chambers, robots, metrology tools, and so on.

Examples of chamber components that may be cleaned according to embodiments described herein include, but are not limited to, a substrate support assembly 148, an electrostatic chuck (ESC) 150, a gas distribution plate, a nozzle, a showerhead, a flow equalizer, a cooling base, a gas feeder, a chamber lid 104, a liner, a ring, a view port, a bellow, and so on. Chamber components that may be cleaned according to embodiments described herein may have hard-to-reach cleaning areas such as sharp corners, screw holes, or deep holes. For example, bellows (e.g., metal bellows) may have a structure that allows the bellow to stretch. The bellow structure may include trenches having a width and depth unreachable to cleanroom wipes or brushes. As such, contamination removal mechanisms that do not require contact with the cleaning surface (e.g., one or more of an ionizer, a heated gas dispenser, a ultrasonic gas dispenser, or a CO₂ snow dispenser) may be desired. Embodiments may be used with chamber components that include one or more apertures as well as with chamber components that do not include any apertures. The chamber component may be a ceramic article having a compositing of at least one of Al₂O₃, AlN, SiO₂, Y₃Al₅O₁₂, Y₄Al₂O₉, Y₂O₃, Er₂O₃, Gd₂O₃, Gd₃Al₅O₁₂, YF₃, Nd₂O₃, Er₄Al₂O₉, Er₃Al₅O₁₂, ErAlO₃, Gd₄Al₂O₉, GdAlO₃, Nd₃Al₅O₁₂, Nd₄Al₂O₉, NdAlO₃, or a ceramic compound composed of Y₄Al₂O₉ and a solid-solution of Y₂O₃—ZrO₂. Alternatively, the chamber component may be another ceramic, may be a metal (e.g., Al, stainless steel, etc.), a metal alloy, or a plastic. The chamber component may also include both a ceramic portion and a non-ceramic (e.g., metal or plastic) portion. As described herein, a cleaning surface may refer to a surface of any component of the processing chamber 100 or other manufacturing equipment described herein, such as FPD processing tools.

In one embodiment, the processing chamber 100 includes a chamber body 102 and a showerhead 130 that enclose an interior volume 106. Alternatively, the showerhead 130 may be replaced by a lid and a nozzle in some embodiments. The chamber body 102 may be fabricated from aluminum, stainless steel or other suitable material. The chamber body 102 generally includes sidewalls 108 and a bottom 110. One or more of the showerhead 130 (or lid and/or nozzle), sidewalls 108 and/or bottom 110 may include a one or more apertures.

An outer liner 116 may be disposed adjacent the sidewalls 108 to protect the chamber body 102. The outer liner 116 may be fabricated to include one or more apertures. In one embodiment, the outer liner 116 is fabricated from aluminum oxide.

An exhaust port 126 may be defined in the chamber body 102 and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewall 108 of the chamber body 102. The showerhead 130 (or lid) may be opened to allow access to the interior volume 106 of the processing chamber 100 and may provide a seal for the processing chamber 100 while closed. A gas panel 158 may be coupled to the processing chamber 100 to provide process and/or cleaning gases to the interior volume 106 through the showerhead 130 or lid and nozzle (e.g., through apertures of the showerhead or lid and nozzle). Showerhead 130 may be used for processing chambers used for dielectric etch (etching of dielectric materials). The showerhead 130 includes a gas distribution plate (GDP) 133 having multiple gas delivery apertures 132 throughout the GDP 133. The showerhead 130 may include the GDP 133 bonded to an aluminum base or an anodized aluminum base. The GDP 133 may be made from Si or SiC, or may be a ceramic such as Y₂O₃, Al₂O₃, YAG, and so forth.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound composed of Y₄Al₂O₉ and a solid-solution of Y₂O₃—ZrO₂. The nozzle may also be a ceramic, such as Y₂O₃, YAG, or the ceramic compound composed of Y₄Al₂O₉ and a solid-solution of Y₂O₃—ZrO₂. The lid, base of showerhead 130, GDP 133 and/or nozzle may be coated with a ceramic layer, which may be composed of one or more of any of the ceramic compositions described herein. The ceramic layer may be a plasma sprayed layer, a physical vapor deposition (PVD) deposited layer, an ion assisted deposition (IAD) deposited layer, or other type of layer. In one embodiment, the ceramic layer may have been coated onto the chamber component prior to formation of apertures. It is noted that any of the chamber components described herein may have ceramic layers or other types of layers, such as anodized aluminum layers.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases). The substrate support assembly 148 is disposed in the interior volume 106 of the processing chamber 100 below the showerhead 130 or lid. The substrate support assembly 148 holds the substrate 144 during processing. A ring 146 (e.g., a single ring) may cover a portion of the electrostatic chuck 150 and may protect the covered portion from exposure to plasma during processing. The ring 146 may be silicon or quartz in one embodiment.

An inner liner 118 may be coated on the periphery of the substrate support assembly 148. The inner liner 118 may be a halogen-containing gas resistant material such as those discussed with reference to the outer liner 116. In one embodiment, the inner liner 118 may be fabricated from the same materials of the outer liner 116. Additionally, the inner liner 118 may be coated with a ceramic layer and/or have one or more apertures passing through.

In one embodiment, the substrate support assembly 148 includes a mounting plate 162 supporting a pedestal 152, and an electrostatic chuck 150. The electrostatic chuck 150 further includes a thermally conductive base 164 and an electrostatic puck 166 bonded to the thermally conductive base by a bond 138, which may be a silicone bond in one embodiment. An upper surface of the electrostatic puck 166 is covered by the ceramic layer 136 in the illustrated embodiment. In one embodiment, the ceramic layer 136 is disposed on the upper surface of the electrostatic puck 166. In another embodiment, the ceramic layer 136 is disposed on the entire exposed surface of the electrostatic chuck 150 including the outer and side periphery of the thermally conductive base 164 and the electrostatic puck 166. The mounting plate 162 is coupled to the bottom 110 of the chamber body 102 and includes passages for routing utilities (e.g., fluids, power lines, sensor leads, etc.) to the thermally conductive base 164 and the electrostatic puck 166.

The thermally conductive base 164 and/or electrostatic puck 166 may include one or more optional embedded heating elements 176, embedded thermal isolators 174 and/or conduits 168, 170 to control a lateral temperature profile of the substrate support assembly 148. The conduits 168, 170 may be fluidly coupled to a fluid source 172 that circulates a temperature regulating fluid through the conduits 168, 170. The embedded thermal isolator 174 may be disposed between the conduits 168, 170 in one embodiment. The heating element 176 is regulated by a heater power source 178. The conduits 168, 170 and heating element 176 may be utilized to control the temperature of the thermally conductive base 164, which may be used for heating and/or cooling the electrostatic puck 166 and a substrate 144 (e.g., a wafer) being processed. The temperature of the electrostatic puck 166 and the thermally conductive base 164 may be monitored using a plurality of temperature sensors 190, 192, which may be monitored using a controller 195.

The electrostatic puck 166 may further include multiple gas passages or apertures such as grooves, mesas and other surface features, which may be formed in an upper surface of the electrostatic puck 166 and/or the ceramic layer 136. The gas passages may be fluidly coupled to a source of a heat transfer (or backside) gas such as helium via apertures drilled in the electrostatic puck 166. In operation, the backside gas may be provided at controlled pressure into the gas passages to enhance the heat transfer between the electrostatic puck 166 and the substrate 144. The electrostatic puck 166 includes at least one clamping electrode 180 controlled by a chucking power source 182. The clamping electrode 180 (or other electrode disposed in the electrostatic puck 166 or conductive base 164) may further be coupled to one or more RF power sources 184, 186 through a matching circuit 188 for maintaining a plasma formed from process and/or other gases within the processing chamber 100. The power sources 184, 186 are generally capable of producing an RF signal having a frequency from about 50 kHz to about 3 GHZ, with a power output of up to about 10,000 Watts.

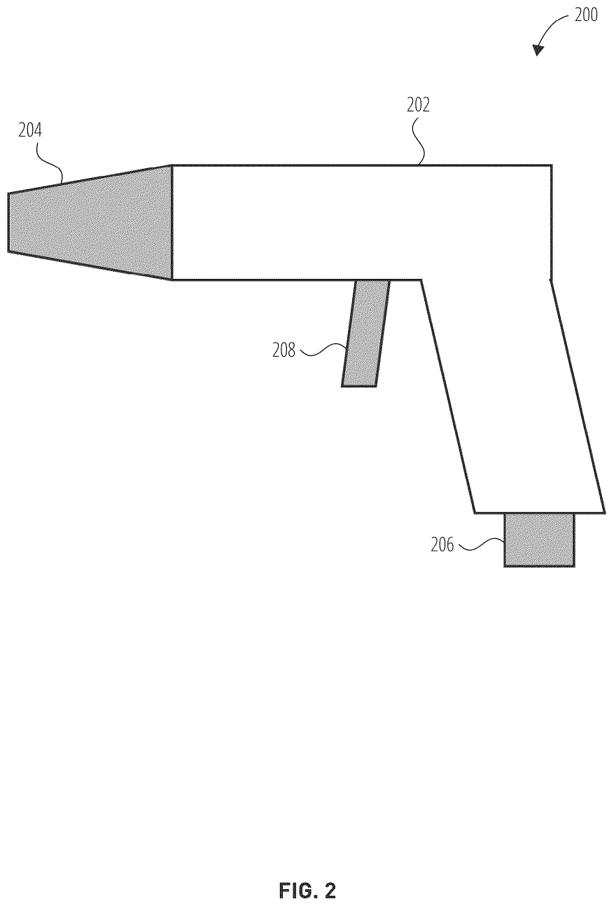

FIG. 2 depicts a cleaning device 200, according to one embodiment. The cleaning device 200 may include a body 202 including a first end coupled to a nozzle 204. In at least one embodiment, the nozzle 204 may be detachable from the cleaning device 200. In some embodiments, multiple different nozzles 204 with different shapes or functions may be operatively coupled to the body 202. The body 202 may also include a second end. The second end of the body 202 may form a handle (as illustrated). Accordingly, in embodiments cleaning device 200 is a hand-held, portable device. A trigger 208 may be attached to the body 202 such that a user holding the cleaning device 200 may pull the trigger 208 to activate the cleaning device 200. The second end of the body may include one or more connectors 206 configured to attach to one or more contamination removal mechanisms, which are described below. At least one of the connectors 206 may also be configured to attach to a vacuum.

The cleaning device 200 may have multiple contamination removal mechanisms. In some embodiments, the cleaning device 200 may be capable of removing particles from cleaning surfaces via two or more different contamination removal mechanisms. Contamination removal mechanisms may include different devices configured to remove or dislodge contaminants from a surface using different techniques. Examples of contamination removal mechanisms include a carbon dioxide (CO₂) snow dispenser, an ionizer, an ultrasonic gas dispenser, and a heated gas dispenser. This group may also include other contamination removal mechanisms, such as a solvent dispenser, a CDA dispenser, a suitable chemical cleaning agent dispenser, a pressurized liquid dispenser (e.g., high-pressure jet of deionized water or other cleaning fluids), a laser cleaning tool, and so on.

A CO₂ snow dispenser, in the context of cleaning components of a chamber as described herein, operates by directing a stream of solid carbon dioxide (CO₂) particles, or “snow,” onto the cleaning surface. In general, the CO₂ snow dispenser removes particles from the cleaning surface through a combination of mechanical force (as the CO₂ particles strike the particles) and thermal shock (caused by the low temperatures of the CO₂ snow).

A CO₂ snow dispenser may store liquid CO₂ under high pressure. As the CO₂ is released (e.g., through the nozzle 204), it undergoes rapid expansion and cooling, forming fine particles (e.g., pellets) or “snow.” In at least one embodiment, compressed air or other gas propels the CO₂ snow from the nozzle at a high velocity. The CO₂ is released by the nozzle (or section of the nozzle), which may be designed to expand and accelerate the CO₂. This CO₂ snow is directed towards the contaminated surface via the nozzle. Upon contact with the surface, the snow particles may sublime, transitioning directly from a solid to a gas state. This sublimation process can provide an effective means of dislodging and removing particles from the surface without leaving any residue, as the CO₂ completely evaporates into the atmosphere. The spray of CO₂ particles may effectively remove contaminants such as dirt, grease, residue, and so on.

Alternative embodiments of the CO₂ snow dispenser may vary in their method of CO₂ delivery, nozzle design, and control systems. For instance, an embodiment may feature an adjustable nozzle system that allows for the modification of the CO₂ snow particle size and/or spray pattern, tailoring the cleaning process to specific types of contaminants or surface geometries. Additionally, some designs may integrate advanced control systems that automate the cleaning process, adjusting the flow rate, temperature, and/or duration of the CO₂ snow application based on real-time feedback from sensors monitoring the cleaning efficacy. The sensors may additionally or alternatively indicate when a surface is cleaned, enabling a user to confidently move on to cleaning a new surface. This automation may help ensure optimal cleaning performance while minimizing manual intervention and potential for human error.

In embodiments where the cleaning device 200 includes a CO₂ snow dispenser, the liquid CO₂ may be stored either within the cleaning device 200 or within a pressurized storage device coupled to the cleaning device 200 via one of the connectors 206. The body 202 may house a hose capable of delivering the CO₂ to the nozzle 204. At least a portion of the nozzle 204 may be adjustable so as to modify the CO₂ snow particle size or spray pattern.

An ionizer (also referred to as an ionizing air blower), in the context of cleaning components of a chamber as described herein, is a device designed to generate and emit ionized gas onto a cleaning surface. A function of the ionizer is to neutralize static charge on surfaces and/or to induce a charge on surfaces, which reduces particle adhesion to the cleaning surface. For example, ions sprayed onto a surface to be cleaned by interact with airborne particles and/or surface contaminants, causing them to become charged and/or to lose a current charge. Charged particles may be attracted to oppositely charged surfaces or repelled from the surface, making it easier to remove the particles from the surfaces. Discharged particles may lose an attractive force that may have been causing the particles to adhere to the surface being cleaned. Generally, an ionizer includes an ion generation mechanism. This mechanism typically employs a high voltage to ionize surrounding air molecules. There are several ways this ionization can be achieved, including but not limited to corona discharge, radioactive sources, and ultraviolet photon emission.

In embodiments where the cleaning device 200 includes an ionizer, the ion generation mechanism may be either housed within the cleaning device 200 or attached to the cleaning device 200 via one of the connectors 206. Once generated, these ions (e.g., ionized air or gas molecules) are directed to a cleaning surface and/or a chamber atmosphere by the nozzle 204.

Upon leaving the nozzle 204, ions may interact with any charged particles present on the cleaning surface or the chamber atmosphere, effectively neutralizing their electrostatic charge. This neutralization reduces the electrostatic forces holding particles to surfaces, allowing them to be more easily removed or preventing their adhesion in the first place. Once the ions have neutralized electrostatic charge holding particles to the cleaning surface or have induced a charge on the particles to cause them to be repelled from the cleaning surface, the nozzle 204 may remove the de-charged particles using suction provided by a vacuum attached to the cleaning device 200 via one of the connectors 206. In at least one embodiment, the cleaning device 200 may also include a vacuum chamber directly attached to one of the connectors 206 or another portion of the cleaning device 200. The vacuum chamber may collect the particles that are dislodged from the cleaning surface by one or more of the contamination removal mechanism(s) of the cleaning device 200.

Alternative embodiments of the ionizer may vary in terms of ion generation method, ion delivery system, or both. For instance, an alternative embodiment might incorporate a pulsed ion generation technique, optimizing ion production efficiency or targeting specific ion species for generation.

In one embodiment, an ultrasonic gas dispenser, in the context of cleaning components of a chamber as described herein, may utilize ultrasonic waves (e.g., optionally at a frequency of 20-400 kHz) to agitate a cleaning gas or solvent, which may enhance the gas's or solvent's ability to remove contaminants from surfaces. The ultrasonic gas dispenser may generate high-frequency sound waves that create microscopic bubbles in the gas phase, which, when they implode, produce a cleaning effect on the cleaning surface. The ultrasonic gas dispenser may atomize a cleaning gas or solvent into fine particles or a mist. The atomized gas may be dispersed onto a surface to be cleaned. The ultrasonic waves agitate the gas particles, creating a cleaning action that helps dislodge and remove contaminants from the surface.

In another embodiment, the ultrasonic gas dispenser may not create the microscopic bubbles as described above. In at least this embodiment, the ultrasonic gas dispenser may dispense gas at a high speed or a high frequency to dislodge and remove particles or other contaminants from the cleaning surface. By dispensing (e.g., ejecting) gas at a high speed toward the cleaning surface, the has molecules carry momentum. This momentum may then be transferred from the gas molecules to the particles. If the force impact is strong enough, this momentum can overcome the adhesive forces holding the particles to the cleaning surface and cause the particles to dislodge. High speed gas can also create a shear force at the interface between the gas and the particles. These shear forces can be strong enough to dislodge the particles from the cleaning surface. By dispensing gas at a high frequency, the gas can induce vibrations on the cleaning surface and within the particles themselves. These vibrations can cause the particles to dislodge from the cleaning surface. If these vibrations match the natural frequency of the particles or the cleaning surface, resonance can occur, significantly amplifying the displacement and potentially dislodging the particles from the cleaning surface.

In general, an ultrasonic gas dispenser includes an ultrasonic generator and a transducer that converts electrical energy into ultrasonic sound waves. These waves are then transmitted into a chamber containing the cleaning gas. The interaction between the ultrasonic waves and the gas leads to the formation of fine gas bubbles that carry kinetic energy. The gas, along with these gas bubbles, are then directed at the cleaning surface. As these bubbles contact the cleaning surface, their implosion results in a localized cleaning action that effectively dislodges particles. Ultrasonic waves may also be directed directly onto the cleaning surface in embodiments.

Alternative embodiments of the ultrasonic gas dispenser may include variations in the frequency and intensity of the ultrasonic waves, adaptation to different types of cleaning gases, or modifications to the delivery system of the gas to the chamber. For instance, one embodiment might feature adjustable ultrasonic frequencies to optimize cleaning effectiveness for various types of contaminants (e.g., different particle sizes, different materials of particles) or cleaning surface materials. Another embodiment could employ a mixture of gases, each selected for their specific cleaning properties, which are then activated ultrasonically in a sequential or simultaneous manner to achieve a comprehensive cleaning effect. Furthermore, some designs may incorporate advanced control systems that allow for more precise regulation of the ultrasonic energy, gas flow rates, and cleaning duration. These systems could be programmed to automatically adjust parameters in real-time, based on feedback from sensors monitoring the cleaning process.

In embodiments where the cleaning device 200 includes an ultrasonic gas dispenser, the ultrasonic generator and the transducer may be housed internally by the cleaning device 200. In these embodiments, the gas bubbles may be generated within the cleaning device 200 and provided to the nozzle 204 to be directed toward the cleaning surface. In other embodiments, the ultrasonic generator and/or transducer may be separate from the cleaning device 200 and coupled to the cleaning device 200 by one of the connectors 206. Here, the ultrasonic generator may be coupled to the cleaning device 200 via a hose attachable to one of the connectors 206.

A heated gas dispenser, in the context of cleaning components of a chamber as described herein, uses temperature elevation to enhance the cleaning efficiency of a gas that is propelled onto a surface to be cleaned. Heating the gas increases its kinetic energy, which in turn improves its ability to dislodge and remove contaminants from surfaces. Additionally, as heated gas flows over a surface being cleaned, the heated gas may cause contaminants to break down and/or vaporize due to kinetic and/or thermal energy imparted by the heated gas impacting the contaminants. Volatile contaminants may be vaporized and carried away in the gas stream. In general, a heated gas dispenser may at least include several components: a gas source, a heating element, and a dispensing mechanism. The gas source supplies the cleaning gas, which is then directed to flow over or through a heating element. This heating element raises the temperature of the gas to a predetermined level, which may be carefully monitored and controlled to optimize cleaning effectiveness while ensuring the safety of the chamber materials. Finally, the heated gas is directed through a nozzle (e.g., the nozzle 204) over the cleaning surface.

Alternative embodiments of the heated gas dispenser may be directed to a variety of operational needs and cleaning scenarios. For example, one variant may incorporate a system for adjusting the temperature of the gas in real-time, allowing for flexibility in cleaning different types of contaminants or surfaces. Another embodiment may integrate advanced monitoring and control systems. These systems could include sensors to measure the temperature, flow rate, and effectiveness of the cleaning process, coupled with feedback loops that automatically adjust the operational parameters of the dispenser for optimized performance. This integration may facilitate a more efficient cleaning process, reducing the consumption of gas and energy while maintaining or improving cleanliness standards.

In embodiments where the cleaning device 200 includes a heated gas dispenser, the gas source and heating element may be housed within the cleaning device 200. In these embodiments, the gas may be heated within the cleaning device 200 before being provided to the nozzle 204 to be dispensed onto the cleaning surface. In other embodiments, one or more of the gas source and/or heating element may be outside of the cleaning device 200 and attached to the cleaning device 200 by one of the connectors 206. For example, the cleaning device 200 may be connected to a gas source by one of the connectors 206, but internally house the heating element near the nozzle 204 to help ensure a uniform heat throughout the dispensed gas.

In some embodiments, the cleaning device 200 may include an interface (e.g., button(s), a switch, a knob, or the like) that allows a user, such as a field engineer, to selectively enable the above-described contamination removal mechanisms. The cleaning device 200 may include multiple modes of operation, each of which may enable one or a combination of contamination removal mechanisms and/or the vacuum. In some embodiments, any combination of cleaning mechanisms may be enabled at a time. The user may base a decision to enable or disable certain contamination removal mechanisms based on sensor data gathered by the cleaning device 200, which is provided to the user (e.g., via a screen, audible notification, or other manner). In one embodiment, this sensor data may be provided by at least a particle density counter.

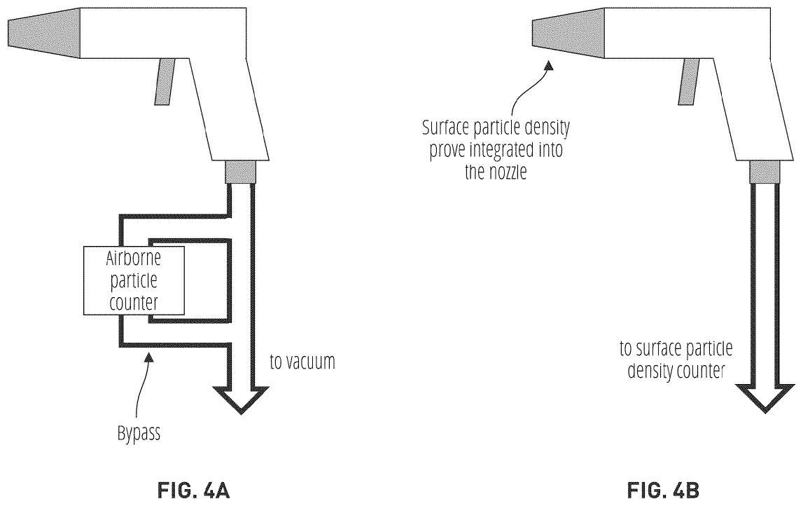

The particle density counter includes an airborne particle counter and/or a surface particle counter. The airborne particle counter may, in real-time, monitor a number or amount of particles that are removed from the cleaning surface by the cleaning device 200. The airborne particle counter may be coupled to a vacuum device coupled to one of the connectors 206, as is illustrated in FIG. 4A. The surface particle counter may include a density probe integrated into the nozzle 204 and a surface particle density counter coupled to one of the connectors 206, as is illustrated in FIG. 4B. In at least one embodiment, the density probe may be an optical system.

The particle counter-airborne or surface—may work by using imaging technology to detect and analyze particles suspended in air or other fluids. In at least one embodiment, the airborne particle counter may include an optical system, which may include one or more cameras or image sensors. These sensors capture image of particles as they pass through a defined detection area. The detection area may be illuminated by a light source (e.g., a laser or LED), to enhance the visibility of particles. The light may interact with these particles, causing them to scatter or reflect light in a manner that makes them detectable by the optical system. Once the particles are identified and distinguished from the background, the particle counter counts and categorizes the particles based on set criteria. This may include classifying particles by size range (e.g., micrometer or nanometer size), concentration, or other parameters relevant to processes of substrate production related to the cleaning surface.

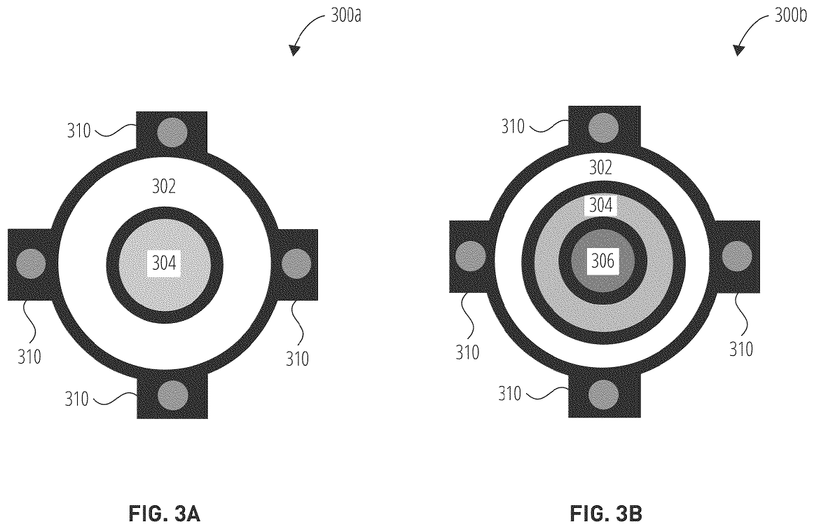

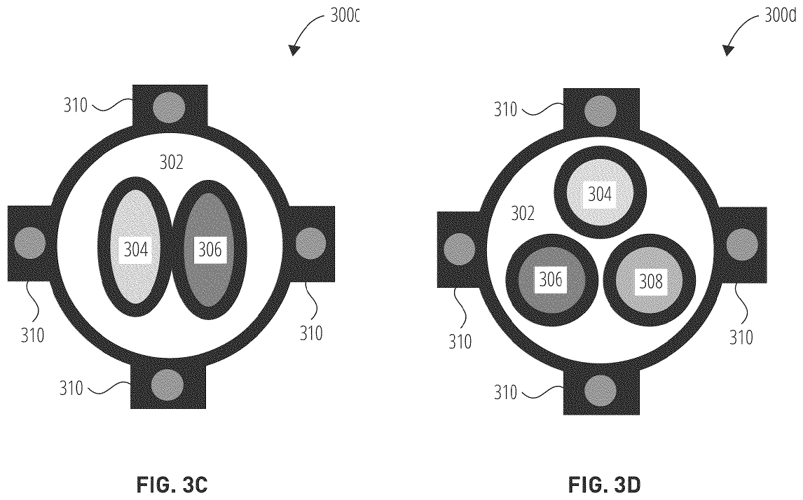

Other sensor data may include information about a temperature, moisture (e.g., humidity), and/or electrostatic charge of the cleaning surface. Sensors integrated into the nozzle 204 may gather this type of information. Sensor data may also include information about what type of material the cleaning surface is composed of. Sensors providing information about the cleaning surface may be one or more of (but not limited to) an optical particle counter, a laser surface analyzer, a thermometer, thermocouples, resistance temperature detectors (RTD), capacitive humidity sensors, resistive humidity sensors, electrostatic field meters, non-contact voltage detectors, or a surface resistivity meter. These sensors integrated into the nozzle 204 are described below in more detail with respect to FIGS. 3A-D.

Other sensor data may also include a gas flow or gas pressure measurement related to one or more of the contamination removal mechanisms. This sensor information may be gathered by sensors attached to a gas line (e.g., flow meter, pressure gauge) either part of the cleaning device 200 (e.g., internally-housed within the body 202, as illustrated, or attached to a gas line connector 206) or attached to a gas line that is attached to the cleaning device 200 via one of the connectors 206.

In at least some embodiments, the cleaning device 200 may include processing logic that selectively enables one or more contamination removal mechanisms based on sensor data gathered by the cleaning device 200. For example, if the cleaning device 200 determines, via sensor data (e.g., provided by the surface resistivity meter), that the cleaning surface is an insulator, the cleaning device 200 may halt an operation of the ionizer. The ionizer may be ineffective at removing particles from an insulative surface because the particles may not be in contact with the cleaning surface due to electrostatic forces. In at least one of these embodiments, the cleaning device 200 may be integrated into a larger automated cleaning system that uses the sensor data to make decisions about which contamination removal mechanism should be used based on the sensor data.

In one embodiment, the cleaning device 200 may determine, based on a particle count provided by the particle counter (airborne or surface) falling below a threshold, that the cleaning surface is clean. Here, the cleaning device 200 may halt operations of one or more contamination removal mechanisms in response to the particle count falling below the threshold.

In some embodiments, the cleaning device 200 may include an interface that allows a user (e.g., field engineer) to selectively enable one of more of the contamination removal mechanisms. The interface may be any suitable type of electronic or mechanical mechanism (e.g., knob, switch, touch screen, button(s), or the like). In at least one embodiment, the user may selectively enable a different contamination removal mechanism based on sensor information that insinuates that the original contamination removal mechanism is ineffective.

The body 202 may house hosing that each direct gas, ions, and/or other cleaning mediums from the connectors 206 to the nozzle 204. For example, the body 202 may house a vacuum channel coupled to both the nozzle 204 and one of the connectors 206. This vacuum channel may be configured to allow the nozzle 204 to gather particles (e.g., particle defects, contamination) from a cleaning surface via suction. As another example, the body 202 may house hosing capable of carrying liquid at high pressure (e.g., between 700 and 900 psi), such as liquid CO₂, or a gas.

In at least one embodiment, the nozzle 204 may be partitioned into different sections that support different contamination removal mechanisms. For example, the nozzle 204 may be split up into three sections: a first section supporting the vacuum, a second section supporting a first contamination removal mechanism, and a third section supporting a second contamination removal mechanism. These first and second contamination removal mechanisms may be different from each other. In at least one embodiment, at least one section supporting a contamination removal mechanism may be adjustable (e.g., to support different CO₂ snow particle sizes or spray patterns for the CO₂ snow dispenser). Exemplary nozzle 204 partitions are illustrated in FIGS. 3A-D. Each of the nozzles 300a-d may have at least a first section 302 and a second section 304. The nozzles 300a-d may be exemplary of the nozzle 204. The first section 302 may support the vacuum as described above. In at least some embodiments, the first section 302 encompasses (e.g., surrounds) the other sections of the nozzle. In embodiments, two or more sections are concentric. In other embodiments, the first section 302 may not encompass other sections of the nozzle. In some embodiments, any sections of the nozzle may encompass (e.g., surround) other sections of the nozzle, as is illustrated in FIG. 3B. The second section 304 may support at least one contamination removal mechanism (e.g., a carbon dioxide (CO₂) snow dispenser, an ionizer, an ultrasonic gas dispenser, a heated gas dispenser, or the like). Alternatively, different contamination removal mechanisms may share a same section of the nozzle. A conduit that connects to the nozzle (e.g., to a same section of the nozzle) may divide and connect to different cleaning mechanisms. In embodiments, one or more valves may connect the conduit to the multiple cleaning mechanisms. Valves may be opened and closed to control which cleaning mechanism is connected to the conduit at a given time. Accordingly, in some embodiments, the section 304 may support more than one contamination removal mechanism. For example, the second section 304 of nozzle 300a may support both the CO₂ snow dispenser and the ultrasonic gas dispenser. In at least some embodiments, the nozzle may include a third section 306 that supports a second contamination removal mechanism. For example, the second section 304 may support the CO₂ snow dispenser and the third section 306 may support another contamination removal mechanism such as the ultrasonic gas dispenser, the ionizer, and/or the heated gas dispenser. The nozzle may also include a fourth section 308 that supports a third contamination removal mechanism. The third contamination removal mechanism may be different than the first and second contamination removal mechanisms. FIG. 3D shows an exemplary nozzle 300d that supports the vacuum and three contamination removal mechanisms.

In at least some embodiments, the nozzle 204 the cleaning device 200 described above may be interchangeable. Due to different uses, compliance restrictions, and/or materials of various types of processing chambers and/or components, different nozzles may be more suitable in different scenarios. In these embodiments, at least some of the nozzles 300a-d may be used interchangeably on the cleaning device 200.

Additionally, sensors 310 may be embedded into the nozzle 204 at different locations. In at least one embodiment, sensors 310 may be embedded on portions of the nozzle outside of the various sections. In another embodiment, the sensors 310 may be placed in other locations than is illustrated in FIGS. 3A-D. These sensors 310 may gather information about the cleaning surface or the atmosphere of the chamber. For example, these sensors 310 may provide data or information about a surface particle density, a temperature, a humidity, or an electrostatic charge of the cleaning surface. These sensors 310 may include, but are not limited to, an optical particle counter, a laser surface analyzer, a thermometer, thermocouples, resistance temperature detectors (RTD), capacitive humidity sensors, resistive humidity sensors, electrostatic field meters, non-contact voltage detectors, or surface resistivity meters. The nozzle 204 may also include other integrated devices, such as an ultraviolet (UV) emitter (e.g., black light) to facilitate visual inspection of the cleaning surface.

An optical particle counter may measure and count particles in the air or on surfaces by analyzing the light scattered by particles when illuminated by a laser or light source. It may quantify particle sizes and concentrations, providing data on the level of particulate contamination.

A laser surface analyzer may utilize laser scanning to measure and map the surface topography, including features like roughness, texture, and imperfections. It generates high-resolution images and data, allowing for detailed analysis of surface conditions.

A thermometer may measure temperature using various principles, including liquid expansion, infrared radiation, or electronic sensors. Thermometers may provide a direct reading of temperature in degrees Celsius or Fahrenheit.

A thermocouple may include two dissimilar metal wires joined at one end, producing a thermoelectric voltage that varies with temperature. This voltage is measured and converted into a temperature reading, offering a way to measure temperature gradients and local temperatures.

An RTD may measure temperature based on the principle that the electrical resistance of certain materials changes predictably with temperature. An RTD may typically use metals like platinum and offer accurate and stable temperature measurements over a wide range.

A capacitive humidity sensor may measure relative humidity by detecting changes in capacitance caused by the absorption or desorption of moisture on a hygroscopic dielectric material. The measured capacitance may be proportional to the relative humidity in the surrounding air.

A resistive humidity sensor may operate by measuring the change in electrical resistance of a hygroscopic medium, which varies with humidity. Resistive humidity sensors may provide a resistance change as moisture content in the air varies, allowing for the measurement of relative humidity.

An electrostatic field meter may detect and measure the strength of static electric fields. These meters can determine the voltage and polarity of charged surfaces without making physical contact, based on the electric field they generate.

A non-contact voltage detector may identify the presence of electrical voltage in equipment, conductors, and circuitry without physical contact. A non-contact voltage detector may operate by sensing the electric field around charged objects, providing a safe means to detect live wires and voltage presence.

A surface resistivity meter may measure the electrical resistivity of a surface by applying a voltage between two points and measuring the current flow. The resulting value may help determine whether a material is an insulator, conductor, or antistatic, based on its ability to conduct electricity on its surface.

In at least one embodiment, instead of the nozzle 204 having multiple sections for the vacuum and the contamination removal mechanisms, multiple nozzles 204 may be concurrently attached to the front end of the cleaning device 200. Each of these nozzles 204 may be dedicated to one or more contamination removal mechanisms. In at least one embodiment, each of these nozzles may also be coupled to the vacuum channel (e.g., provide suction via a section of each nozzle). In another embodiment, only one nozzle of the multiple nozzles 204 may be coupled to the vacuum channel while the remaining nozzles are dedicated to one or more contamination removal mechanisms.

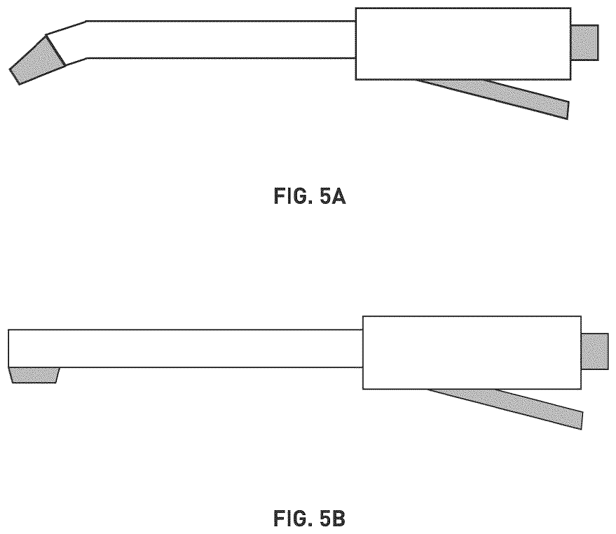

In some embodiments, the cleaning device 200 may include an elongated portion to extend a reach of the cleaning device 200. The reach of the cleaning device 200 may be extended to reach areas of chamber components (e.g., bellows, deep holes, or the like) that a field engineer may not be able to otherwise reach. In one embodiment, the body 202 may be elongated as can be seen in FIGS. 5A-B. In some embodiments, the nozzle 204 may be similarly elongated. Additionally, to facilitate the nozzle 204 contacting the cleaning area, the nozzle 204 may be positioned or formed at a non-parallel angle to the elongated portion of the body 202 or the elongated portion of the nozzle 204.

Notwithstanding the FIGS. 3A-D, it is to be understood that these exemplary nozzles 300a-d are provided for the purpose of example only and are not intended to limit the scope of the present disclosure. The nozzle (e.g., nozzle 204) may be embodied in various forms and should not be construed as confined to the specific embodiments set forth herein. Those skilled in the art will appreciate that the nozzle can also be implemented in a multitude of different configurations, shapes, and materials, each varying from the depicted examples.

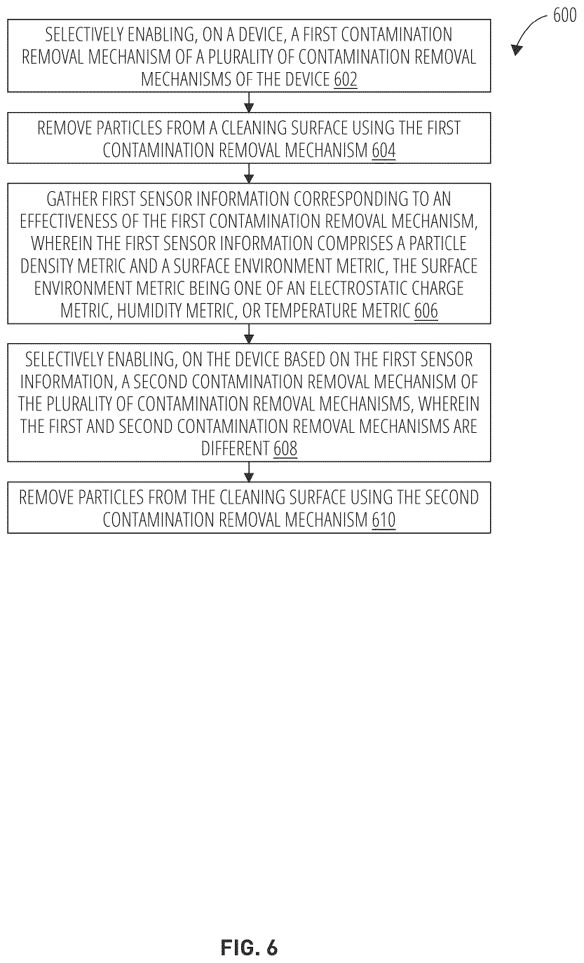

FIG. 6 illustrates a method 600 of using a cleaning device, according to one embodiment. The method 600 may be performed by processing logic that may comprise hardware (e.g., circuitry, dedicated logic, programmable logic, microcode, etc.), software (e.g., instructions run on a processing device to perform hardware simulation), firmware, or a combination thereof. In some embodiments, the method 600 may be performed by a cleaning device, such as the cleaning device 200 as described above with respect to FIG. 2. Alternatively, the method 600 may be performed by another device (e.g., a robot) or a person (e.g., a field engineer) using the cleaning device 200. A device other than the cleaning device 200 may also be capable of performing the operations of the method 600.

At block 602, a first contamination removal mechanism is selectively enabled on a device. The first contamination removal may be of a plurality of contamination removal mechanisms. The first contamination removal mechanism may be manually selected by a user, or may be automatically selected based, for example, on sensor data collected by one or more sensors of a cleaning device. For example, a nozzle of the cleaning device housing one or more sensors may be pointed at a surface to be cleaned. One or more sensors of the cleaning device may generate one or more measurements related to the surface to be cleaned, which may indicate a particle count, a material type, a temperature, a static charge, and/or other information. Based on such information, processing logic of the cleaning device may automatically select a cleaning mode that applies the first contamination removal mechanism.

At block 604, the device removes particles from a cleaning surface using the first contamination removal mechanism.

At block 606, the device gathers first sensor information corresponding to an effectiveness of the first contamination removal mechanism. The first sensor information may include a particle density metric and a surface environment metric. The surface environment metric may be one of an electrostatic charge metric, a humidity metric, or a temperature metric.

At block 608, a second contamination removal mechanism is selectively enabled on the device. The second contamination removal mechanism may be selectively enabled based on the first sensor information. The second contamination removal mechanism may be of the plurality of removal mechanisms. The first and second contamination removal mechanisms may be different. The first contamination removal mechanism may or may not be deactivated. Accordingly, the first and second contamination removal mechanisms may function in parallel in some embodiments. In some embodiments, the second contamination removal mechanism is automatically selected responsive to a user directing the nozzle of the cleaning device to a new part, which may be made of a different material than the first part, may have a different level of contamination than the first part, and so on. In some embodiments, the cleaning device automatically selects the second contamination removal mechanism based on updated sensor data collected for the second part. Alternatively, the user may manually set the cleaning device to a second mode that applies the second contamination removal mechanism.

At block 610, the device removes particles from the cleaning surface using the second contamination removal mechanism.

In at least one embodiment, the device may also collect, by a vacuum, particles dislodged from the cleaning surface. These particles may be processed using an airborne particle counter to assess a cleanliness of the surface being cleaned in some instances. Based on the particle count, a user may determine whether to continue cleaning a current surface or to move on to a new surface. In some embodiments, processing logic of the cleaning device determines when the particle density falls below a threshold, and outputs a recommendation to move on to a new surface once the particle count falls below the threshold. For example, the cleaning device may output a green light when a particle count is below the threshold, and a red, yellow or orange light when the particle count is above the threshold. In some embodiments, different colors may be associated with different particle counts, and the cleaning device may output light of a color selected based on the detected particle count. In some embodiments, the cleaning device includes a display that outputs the particle count. In some embodiments, the cleaning device includes an optical particle counter and an airborne particle counter, and average particle counts from the two particle counting sensors. This may provide an increased particle count accuracy in some embodiments.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present invention. Thus, the specific details set forth are merely exemplary. Particular embodiments may vary from these exemplary details and still be contemplated to be within the scope of the present disclosure.

Reference throughout this specification to “one embodiment” or “an embodiment” indicates that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of embodiments of the invention should, therefore, be determined with reference to the appended claims, along with the full scope of equivalents to which such claims are entitled.

What is claimed is:

1. A device, comprising:
a body having a first end forming a nozzle and a second end configured to couple to a particle density counter, wherein the nozzle is partitioned into a plurality of sections;
a vacuum channel extending through the body from the nozzle to the second end;
a first section of the nozzle coupled to the vacuum channel;
a second section of the nozzle coupled to a first contamination removal mechanism of a plurality of contamination removal mechanisms;
a third section of the nozzle coupled to a second contamination removal mechanism of the plurality of contamination removal mechanisms; and
a selection mechanism configured to selectively enable at least one of the plurality of contamination removal mechanisms.

2. The device of claim 1, wherein the first contamination removal mechanism and the second contamination removal mechanism are each selected from a group selected from: a carbon dioxide (CO₂) snow dispenser, an ionizer, an ultrasonic gas dispenser, and a heated gas dispenser.

3. The device of claim 1, wherein the nozzle further comprises one or more sensors each configured to measure one of an electrostatic charge, a moisture, or a temperature of a cleaning surface.

4. The device of claim 3, wherein the one or more sensors comprise a first sensor to measure a temperature of the cleaning surface and a second sensor to measure one of the electrostatic charge or the moisture of the cleaning surface.

5. The device of claim 1, wherein the nozzle comprises a fourth section configured to emit ultraviolet (UV) light onto a cleaning surface.

6. The device of claim 1, wherein the body comprises an elongated portion between the first and second ends to extend a reach of the device, and wherein the first end forms a nozzle at a non-parallel angle to the elongated portion of the body.

7. The device of claim 1, wherein the device is a hand-held device, and wherein the body comprises a handle.

8. The device of claim 1, wherein the first section of the nozzle encompasses the second and third sections of the nozzle.

9. The device of claim 1, further comprising a fourth section of the nozzle coupled to a third contamination removal mechanism of the plurality of contamination removal mechanisms.

10. A device, comprising:
a body having a first end forming a plurality of nozzles and a second end configured to couple to a particle density counter;
a vacuum channel extending through the body from the first end to the second end, wherein one or more of the plurality of nozzles is coupled to the vacuum channel;
a first nozzle of the plurality of nozzles coupled to a first contamination removal mechanism of a plurality of contamination removal mechanisms;
a second nozzle of the plurality of nozzles coupled to a second contamination removal mechanism of a plurality of contamination removal mechanisms; and
a selection mechanism configured to selectively enable one of the plurality of contamination removal mechanisms.

11. The device of claim 10, wherein the first contamination removal mechanism and the second contamination removal mechanism are each selected from a group selected from: a carbon dioxide (CO₂) snow dispenser, an ionizer, an ultrasonic gas dispenser, and a heated gas dispenser.

12. The device of claim 10, wherein the first end of the body further comprises one or more sensors each configured to measure one of an electrostatic charge, a moisture, or a temperature of a cleaning surface.

13. The device of claim 12, wherein the one or more sensors comprise a first sensor to measure a temperature of the cleaning surface and a second sensor to measure one of the electrostatic charge or the moisture of the cleaning surface.

14. The device of claim 10, wherein the first end is configured to emit ultraviolet (UV) light onto a cleaning surface.

15. The device of claim 10, wherein the body comprises an elongated portion between the first and second ends to extend a reach of the device, and wherein the first end forms at least one of the plurality of nozzles at a non-parallel angle to the elongated portion of the body.

16. The device of claim 10, wherein the device is a hand-held device, and wherein the body comprises a handle.

17. The device of claim 10, wherein the vacuum channel is coupled to a third nozzle of the plurality of nozzles, and wherein the third nozzle encompasses the first and second nozzles.

18. A method comprising:
selectively enabling a first contamination removal mechanism of a plurality of contamination removal mechanisms of a device;
removing, by the device, particles from a cleaning surface using the first contamination removal mechanism;
gathering, by the device, first sensor information corresponding to an effectiveness of the first contamination removal mechanism, wherein the first sensor information comprises at least one of a particle density metric or a surface environment metric, the surface environment metric being one of an electrostatic charge metric, a humidity metric, or a temperature metric;
selectively enabling, based on the first sensor information, a second contamination removal mechanism of the plurality of contamination removal mechanisms of the device, wherein the first and second contamination removal mechanisms are different; and
removing, by the device, particles from the cleaning surface using the second contamination removal mechanism.

19. The method of claim 18, wherein the first contamination removal mechanism and the second contamination removal mechanism are each selectively enabled from a group selected from: a carbon dioxide (CO₂) snow dispenser, an ionizer, an ultrasonic gas dispenser, and a heated gas dispenser.

20. The method of claim 18, wherein the method further comprises collecting, by a vacuum of the device, particles dislodged from the cleaning surface by the first and second contamination removal mechanisms.
